(19) United States
(12) Patent Application Publication
(10) Pub. No.: US 2025/0275117 A1
(43) Pub. Date: Aug. 28, 2025

(54) VARIABLE LOGIC IN MEMORY CELL

(71) Applicant: KOREA UNIVERSITY RESEARCH AND BUSINESS, Seoul (KR)

(72) Inventors: Sang Sig KIM, Seoul (KR); Kyoung Ah CHO, Seoul (KR); Eun Woo BAEK, Seoul (KR); Ju Hee JEON, Seoul (KR); Jae Min SON, Seongnam-si (KR); Taek Ham KIM, Pyeongtaek-si (KR); Ye Jin YANG, Siheung-si (KR)

(73) Assignee: Korea University Research and Business Foundation, Seoul (KR)

(21) Appl. No.: 18/575,617

(22) PCT Filed: Oct. 13, 2022
(86) PCT No.: PCT/KR2022/015457

§ 371 Date: Jul. 10, 2024

(30) Foreign Application Priority Data
Oct. 14, 2021 (KR) 10-2021-0136713

(51) Int. Cl. H10B 12/00; G11C 11/404; H03K 19/177

(52) U.S. Cl. CPC H10B 12/20; G11C 11/404; H03K 19/177

(57) ABSTRACT

The present invention relates to a reconfigurable logic-in-memory cell consisting of triple-gate feedback memory elements. The reconfigurable logic-in-memory cell according to one embodiment of the present invention includes a plurality of triple-gate feedback memory elements including a drain region, a channel region, a source region, and a gate region where first and second programming gate electrodes and a control gate electrode are formed on the channel region.

### TECHNICAL FIELD

The present invention relates to a reconfigurable logic-in-memory cell consisting of triple-gate feedback memory elements, and more particularly, to technology for implementing a reconfigurable logic-in-memory cell that provides a logical operation function and a memory function using triple-gate feedback memory elements driven by a positive feedback loop.

### BACKGROUND ART

In a conventional von Neumann-based computer system, a processor and a memory are separated and data are transmitted through a bus.

As computing performance improves, a bottleneck phenomenon occurs due to a difference in data processing speed between a processor and a memory, and there are limits to processing large amounts of data.

That is, the von Neumann-based system, which is a product of revolutionary development in the semiconductor industry, has improved the integration density and performance of modern computers, but has the disadvantage of consuming much energy and having long data transmission and standby times due to the physical separation between a processor and a memory hierarchy.

Considering the increase in data-intensive applications such as 5G communication standards, Internet of Things (IoT), and Artificial Intelligence (AI) after the Fourth Industrial Revolution, a new computing paradigm is an essential requirement for large-scale data processing.

To solve the above-mentioned problems, research is being actively conducted on logic-in-memory (LIM) technology that combines calculation and memory functions.

According to the logic-in-memory technology, since the calculating function of a processor and the memory function of a memory are performed in the same space, the time and power required during data transmission may be reduced, and the integration of the system may be greatly improved.

The conventional logic-in-memory technology has been actively researched based on static random-access memory (SRAM) and dynamic RAM (DRAM), which are volatile memory elements, and resistive RAM (ReRAM), magnetoresistive RAM (MRAM), and phase-change RAM (PCRAM), which are non-volatile memory elements.

In the case of the logic-in-memory technology based on volatile memory elements, a large number of transistors are required for stable operation. Additionally, the technology has disadvantages such as a large overall area and high power consumption.

In addition, in the case oflogic-in-memory technology based on a non-volatile memory element, a complex manufacturing process is required because non-silicon materials are used. In addition, this technology has low element uniformity and stability, making it difficult to put into practical use.

In addition, previously researched logic-in-memory technologies cannot implement all basic CMOS logic operations in one cell and have low integration because individual circuitry and wiring are required for each logic operation.

Accordingly, the development of a reconfigurable logic-in-memory cell capable of being fabricated using a silicon-based CMOS process, performing all basic logic operations within one cell, and storing the operation result values is required.

### DISCLOSURE

### Technical Problem

Therefore, the present invention has been made in view of the above problems, and it is one object of the present invention to implement a reconfigurable logic-in-memory cell that provides a logical operation function and a memory function using triple-gate feedback memory elements driven by a positive feedback loop.

It is another object of the present invention to implement a reconfigurable logic-in-memory cell using triple-gate feedback memory elements, which are silicon-based feedback memory elements fabricated using the conventional CMOS process.

It is still another object of the present invention to implement a reconfigurable logic-in-memory cell that performs all basic logical operations using triple-gate feedback memory elements having channel-type variable characteristics and remembers the results of the performed logical operations.

It is still another object of the present invention to improve processing speed and integration limitations due to the data bottleneck phenomenon through the fusion of logical operation and storage functions.

It is yet another object of the present invention to improve standby power efficiency with excellent memory characteristics related to maintaining logical operation values without structural change or external bias by using channel-type variable characteristics.

### Technical Solution

In accordance with one aspect of the present invention, provided is a reconfigurable logic-in-memory cell including a plurality of triple-gate feedback memory elements including a drain region, a channel region, a source region, and a gate region where first and second programming gate electrodes and a control gate electrode are formed on the channel region, wherein, in each of the triple-gate feedback memory elements, the channel region below the first and second programming gate electrodes performs any one channel operation of first and second channel operations depending on a level of a program voltage (V_{PG}) applied through the first and second programming gate electrodes, any one of an on state and an off state is determined based on a level of a control voltage (V_{CG}) applied through the control gate electrode, and a logical operation function and a memory function are performed based on a level of an output voltage (V_{OUT}) that changes depending on the any one state in the any one channel operation performed.

The drain region may be in a p-doped state, the source region may be in an n-doped state, and the channel region may be in an intrinsic state. The channel region below the first and second programming gate electrodes may operate as an n channel corresponding to the first channel operation when a level of the program voltage (V_{PG}) is a high level, and may operate as a p channel corresponding to the second channel operation when a level of the program voltage (V_{PG}) is a low level.

When the channel region below the first and second programming gate electrodes performs the first channel operation, each of the triple-gate feedback memory elements may be determined to be in an on state when a level of the applied control voltage (V_{CG}) is a high level, and may be determined to be in an off state when a level of the applied control voltage (V_{CG}) is a low level.

In each of the triple-gate feedback memory elements, when the channel region below the first and second programming gate electrodes performs the first channel operation, when a level of the applied control voltage (V_{CG}) increases from zero to a high level, a height of a potential barrier between the channel region below the control gate electrode and the channel region below the second programming gate electrode adjacent to the source region may be lowered, and due to the lowered potential barrier, a first positive feedback loop in which electrons are injected from the source region may occur, resulting in the on state in which current flows.

When the channel region below the first and second programming gate electrodes performs the second channel operation, each of the triple-gate feedback memory elements may be determined to be in an off state when a level of the applied control voltage (V_{CG}) is a high level, and may be determined to be in an on state when a level of the applied control voltage (V_{CG}) is a low level.

In each of the triple-gate feedback memory elements, when the channel region below the first and second programming gate electrodes performs the second channel operation, when a level of the applied control voltage (V_{CG}) decreases from zero to a low level, a height of a potential barrier between the channel region below the control gate electrode and the channel region below the first programming gate electrode adjacent to the drain region may be lowered, and due to the lowered potential barrier, a second positive feedback loop in which holes are injected from the drain region may occur, resulting in the on state in which current flows.

The reconfigurable logic-in-memory cell may consist of any one circuitry structure of a first circuitry structure consisting of a plurality of first parallel connections where drain regions of two triple-gate feedback memory elements of the triple-gate feedback memory elements are connected to each other and source regions thereof are connected to each other; and a second circuitry structure consisting of a plurality of second parallel connections where a common drain region and a common source region between a first serial connection where a drain region and source region of two triple-gate feedback memory elements of four triple-gate feedback memory elements of the triple-gate feedback memory elements are connected in series and a second serial connection where a drain region and source region of the remaining two triple-gate feedback memory elements are connected in series are connected.

When the reconfigurable logic-in-memory cell has the first circuitry structure, a drain voltage (V_{DD}) may be applied to a drain terminal of a first one of the first parallel connections, and a source voltage (V_{SS}) may be applied to a source terminal of a last one of the first parallel connections. When the reconfigurable logic-in-memory cell has the second circuitry structure, a drain voltage (V_{DD}) may be applied to a drain terminal of a first one of the second parallel connections, and a source voltage (V_{SS}) may be applied to a source terminal of a last one of the second parallel connections.

The reconfigurable logic-in-memory cell may have the second circuitry structure; triple-gate feedback memory elements constituting a first one of the second parallel connections may perform the second channel operation, and triple-gate feedback memory elements constituting a last one of the second parallel connections may perform the first channel operation; and the reconfigurable logic-in-memory cell may perform the logical operation function in which a level of the output voltage (V_{OUT}) is a high level when a level of the control voltage (V_{CG}) is a low level, and a level of the output voltage (V_{OUT}) is a low level when a level of the control voltage (V_{CG}) is a high level.

The reconfigurable logic-in-memory cell may have the second circuitry structure; triple-gate feedback memory elements constituting a first one of the second parallel connections may perform the first channel operation, and triple-gate feedback memory elements constituting a last one of the second parallel connections may perform the second channel operation; and the reconfigurable logic-in-memory cell may perform the logical operation function in which a level of the output voltage (V_{OUT}) is a low level when a level of the control voltage (V_{CG}) is a low level, and a level of the output voltage (V_{OUT}) is a high level when a level of the control voltage (V_{CG}) is a high level.

The reconfigurable logic-in-memory cell may have the second circuitry structure; triple-gate feedback memory elements constituting a first one of the second parallel connections may perform the second channel operation, and triple-gate feedback memory elements constituting a last one of the second parallel connections may perform the first channel operation; a first control voltage (V_{A}) of the control voltages (V_{CG}) may be applied to a left side of the first one of the second parallel connections and an upper side of the last one of the second parallel connections, and a second control voltage (V_{B}) of the control voltages (V_{CG}) may be applied to a right side of the first one of the second parallel connections and a lower side of the lase one of the second parallel connections; and the reconfigurable logic-in-memory cell may perform the logical operation function in which a level of the output voltage (V_{OUT}) is a high level when only one of levels of the first control voltage (V_{A}) and the second control voltage (V_{B}) is a high level or both levels are low levels, and a level of the output voltage (V_{OUT}) is a low level when both levels of the first control voltage (V_{A}) and the second control voltage (V_{B}) are high levels.

The reconfigurable logic-in-memory cell may have the second circuitry structure; triple-gate feedback memory elements constituting a first one of the second parallel connections may perform the second channel operation, and triple-gate feedback memory elements constituting a last one of the second parallel connections may perform the first channel operation; a first control voltage (V_{A}) of the control voltages (V_{CG}) may be applied to an upper side of the first one of the second parallel connections and a left side of the last one of the second parallel connections, and a second control voltage (V_{B}) of the control voltages (V_{CG}) may be applied to a lower side of the first one of the second parallel connections and a right side of the last one of the second parallel connections; and the reconfigurable logic-in-memory cell may perform the logical operation function in which a level of the output voltage (V_{OUT}) is a low level when only one of levels of the first control voltage (V_{A}) and the second control voltage (V_{B}) is a low level or both levels are high levels, and a level of the output voltage (V_{OUT}) is a high level when both levels of the first control voltage (V_{A}) and the second control voltage (V_{B}) are low levels.

The reconfigurable logic-in-memory cell may have the second circuitry structure; triple-gate feedback memory elements constituting a first one of the second parallel connections may perform the first channel operation, and triple-gate feedback memory elements constituting a last one of the second parallel connections may perform the second channel operation; a first control voltage (V_{A}) of the control voltages (V_{CG}) may be applied to an upper side of the first one of the second parallel connections and a left side of the last one of the second parallel connections, and a second control voltage (V_{B}) of the control voltages (V_{CG}) may be applied to a lower side of the first one of the second parallel connections and a right side of the last one of the second parallel connections; and the reconfigurable logic-in-memory cell may perform the logical operation function in which a level of the output voltage (V_{OUT}) is a low level when any one of levels of the first control voltage (V_{A}) and the second control voltage (V_{B}) is a low level, and a level of the output voltage (V_{OUT}) is a high level when both levels of the first control voltage (V_{A}) and the second control voltage (V_{B}) are high levels.

The reconfigurable logic-in-memory cell may have the second circuitry structure; triple-gate feedback memory elements constituting a first one of the second parallel connections may perform the first channel operation, and triple-gate feedback memory elements constituting a last one of the second parallel connections may perform the second channel operation; a first control voltage (V_{A}) of the control voltages (V_{CG}) may be applied to a left side of the first one of the second parallel connections and an upper side of the last one of the second parallel connections, and a second control voltage (V_{B}) of the control voltages (V_{CG}) may be applied to a right side of the first one of the second parallel connections and a lower side of the last one of the second parallel connections; and the reconfigurable logic-in-memory cell may perform the logical operation function in which a level of the output voltage (V_{OUT}) is a high level when any one of levels of the first control voltage (V_{A}) and the second control voltage (V_{B}) is a high level, and a level of the output voltage (V_{OUT}) is a low level when both levels of the first control voltage (V_{A}) and the second control voltage (V_{B}) are low levels.

The reconfigurable logic-in-memory cell may have the second circuitry structure; a left side of triple-gate feedback memory elements constituting a first one of the second parallel connections may perform the first channel operation, a right side of the triple-gate feedback memory elements constituting the first one of the second parallel connections may perform the second channel operation, an upper left side of triple-gate feedback memory elements constituting a last one of the second parallel connections may perform the second channel operation, an upper right side of the triple-gate feedback memory elements constituting the last one of the second parallel connections may perform the first channel operation, a lower left side of the triple-gate feedback memory elements constituting the last one of the second parallel connections may perform the first channel operation, and a lower right side of the triple-gate feedback memory elements constituting the last one of the second parallel connections may perform the second channel operation; a first control voltage (V_{A}) of the control voltages (V_{CG}) may be applied to an upper side of the first one of the second parallel connections and an upper side of the last one of the second parallel connections, and a second control voltage (V_{B}) of the control voltages (V_{CG}) may be applied to a lower side of the first one of the second parallel connections and a lower side of the last one of the second parallel connections; and the reconfigurable logic-in-memory cell may perform the logical operation function in which a level of the output voltage (V_{OUT}) is a high level when levels of the first control voltage (V_{A}) and the second control voltage (V_{B}) are the same, and a level of the output voltage (V_{OUT}) is a low level when levels of the first control voltage (V_{A}) and the second control voltage (V_{B}) are different.

The reconfigurable logic-in-memory cell may have the second circuitry structure; an upper left side of triple-gate feedback memory elements constituting a first one of the second parallel connections may perform the second channel operation, an upper right side of the triple-gate feedback memory elements constituting the first one of the second parallel connections may perform the first channel operation, a lower left side of the triple-gate feedback memory elements constituting the first one of the second parallel connections may perform the first channel operation, a lower right side of the triple-gate feedback memory elements constituting the first one of the second parallel connections may perform the second channel operation, a left side of triple-gate feedback memory elements constituting a last one of the second parallel connections may perform the first channel operation, and a right side of the triple-gate feedback memory elements constituting the last one of the second parallel connections may perform the second channel operation; a first control voltage (V_{A}) of the control voltages (V_{CG}) may be applied to an upper side of the first one of the second parallel connections and an upper side of the last one of the second parallel connections, and a second control voltage (V_{B}) of the control voltages (V_{CG}) may be applied to a lower side of the first one of the second parallel connections and a lower side of the last one of the second parallel connections; and the reconfigurable logic-in-memory cell may perform the logical operation function in which a level of the output voltage (V_{OUT}) is a low level when levels of the first control voltage (V_{A}) and the second control voltage (V_{B}) are the same, and a level of the output voltage (V_{OUT}) is a high level when levels of the first control voltage (V_{A}) and the second control voltage (V_{B}) are different.

The reconfigurable logic-in-memory cell may perform the memory function by maintaining a level of the output voltage (V_{OUT}) when the drain voltage (V_{DD}), the source voltage (V_{SS}), the program voltage (V_{PG}), and the control voltage (V_{CG}) are applied at a zero level.

### Advantageous Effects

The present invention can implement a reconfigurable logic-in-memory cell that provides a logical operation function and a memory function using triple-gate feedback memory elements driven by a positive feedback loop.

The present invention can implement a reconfigurable logic-in-memory cell using triple-gate feedback memory elements, which are silicon-based feedback memory elements fabricated using the conventional CMOS process.

The present invention can implement a reconfigurable logic-in-memory cell that performs all basic logical operations using triple-gate feedback memory elements having channel-type variable characteristics and remembers the results of the performed logical operations.

The present invention can improve processing speed and integration limitations due to the data bottleneck phenomenon through the fusion of logical operation and storage functions.

The present invention can improve standby power efficiency with excellent memory characteristics related to maintaining logical operation values without structural change or external bias by using channel-type variable characteristics.

### DESCRIPTION OF DRAWINGS

FIGS. 1A and 1B are diagrams explaining a triple-gate feedback memory element constituting a reconfigurable logic-in-memory cell according to one embodiment of the present invention.

FIGS. 2A and 2B are diagrams explaining the circuitry symbols of a triple-gate feedback memory element according to one embodiment of the present invention.

FIGS. 3A to 3F are diagrams explaining the operating principle of a triple-gate feedback memory element according to one embodiment of the present invention.

FIGS. 4A and 4B are diagrams explaining the circuitry diagram of a reconfigurable logic-in-memory cell according to one embodiment of the present invention.

FIGS. 5A and 5B are diagrams explaining the NOT gate operation of a reconfigurable logic-in-memory cell according to one embodiment of the present invention.

FIGS. 6A and 6B are diagrams explaining the YES gate operation of a reconfigurable logic-in-memory cell according to one embodiment of the present invention.

FIGS. 7A and 7B are diagrams explaining the NAND gate operation of a reconfigurable logic-in-memory cell according to one embodiment of the present invention.

FIGS. 8A and 8B are diagrams explaining the NOR gate operation of a reconfigurable logic-in-memory cell according to one embodiment of the present invention.

FIGS. 9A and 9B are diagrams explaining the AND gate operation of a reconfigurable logic-in-memory cell according to one embodiment of the present invention.

FIGS. 10A and 10B are diagrams explaining the OR gate operation of a reconfigurable logic-in-memory cell according to one embodiment of the present invention.

FIGS. 11A and 11B are diagrams explaining the XNOR gate operation of a reconfigurable logic-in-memory cell according to one embodiment of the present invention.

FIGS. 12A and 12B are diagrams explaining the XOR gate operation of a reconfigurable logic-in-memory cell according to one embodiment of the present invention.

### BEST MODE

Hereinafter, the embodiments of the present invention will be described in detail with reference to the drawings.

However, it should be understood that the present invention is not limited to the embodiments according to the concept of the present invention, but includes changes, equivalents, or alternatives falling within the spirit and scope of the present invention.

In the following description of the present invention, detailed description of known functions and configurations incorporated herein will be omitted when it may make the subject matter of the present invention unclear.

In addition, the terms used in the specification are defined in consideration of functions used in the present invention, and can be changed according to the intent or conventionally used methods of clients, operators, and users. Accordingly, definitions of the terms should be understood on the basis of the entire description of the present specification.

In description of the drawings, like reference numerals may be used for similar elements.

The singular expressions in the present specification may encompass plural expressions unless clearly specified otherwise in context.

In this specification, expressions such as “A or B” and “at least one of A and/or B” may include all possible combinations of the items listed together.

Expressions such as “first” and “second” may be used to qualify the elements irrespective of order or importance, and are used to distinguish one element from another and do not limit the elements.

It will be understood that when an element (e.g., first) is referred to as being “connected to” or “coupled to” another element (e.g., second), the first element may be directly connected to the second element or may be connected to the second element via an intervening element (e.g., third).

As used herein, “configured to” may be used interchangeably with, for example, “suitable for”, “ability to”, “changed to”, “made to”, “capable of”, or “designed to” in terms of hardware or software.

In some situations, the expression “device configured to” may mean that the device “may do ˜” with other devices or components.

For example, in the sentence “processor configured to perform A, B, and C”, the processor may refer to a general purpose processor (e.g., CPU or application processor) capable of performing corresponding operation by running a dedicated processor (e.g., embedded processor) for performing the corresponding operation, or one or more software programs stored in a memory device.

In addition, the expression “or” means “inclusive or” rather than “exclusive or”.

That is, unless mentioned otherwise or clearly inferred from context, the expression “x uses a or b” means any one of natural inclusive permutations.

Terms, such as “unit” or “module”, etc., should be understood as a unit that processes at least one function or operation and that may be embodied in a hardware manner, a software manner, or a combination of the hardware manner and the software manner.

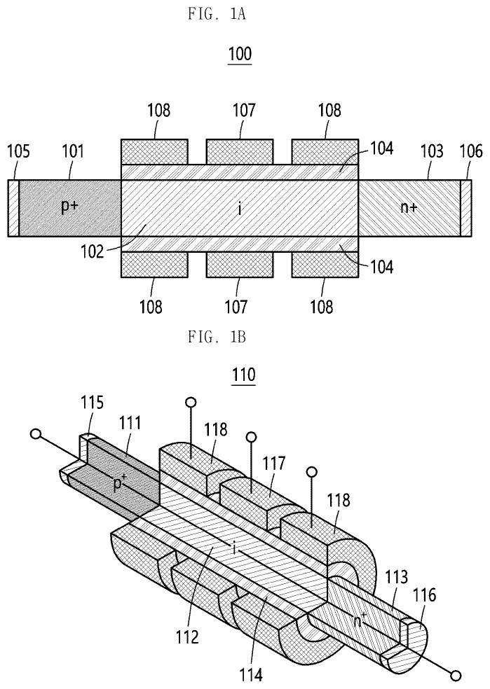

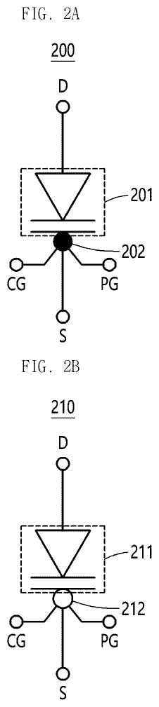

FIGS. 1A and 1B are diagrams explaining a triple-gate feedback memory element constituting a reconfigurable logic-in-memory cell according to one embodiment of the present invention.

FIG. 1A shows the cross-sectional view of the triple-gate feedback memory element constituting a reconfigurable logic-in-memory cell according to one embodiment of the present invention, and FIG. 1B shows the three-dimensional view of the triple-gate feedback memory element.

Referring to FIG. 1A, a triple-gate feedback memory element 100 according to one embodiment of the present invention includes a drain region 101, a channel region 102, a source region 103, and a gate region, and the gate region includes a first and second programming gate electrodes 108 and a control gate electrode 107, which are formed on a gate insulating film 104.

For example, a drain electrode 105 may be formed in the drain region 101, and a source electrode 106 may be formed in the source region 103.

According to one embodiment of the present invention, the triple-gate feedback memory element 100 includes the drain region 101, the channel region 102, and the source region 103, which are p-i-n nanostructures.

For example, the drain region 101 may be in a p-doped state, the source region 103 may be in an n-doped state, and the channel region 102 may be in an intrinsic state.

In the channel region 102, the channel region below the first and second programming gate electrodes 108 may operate as an n channel corresponding to a first channel operation when the level of a program voltage (V_{PG}) is a high level, and may operate as a p channel corresponding to a second channel operation when the level of the program voltage (V_{PG}) is a low level.

A plurality of triple-gate feedback memory elements 100 may form a reconfigurable logic-in-memory cell.

In the triple-gate feedback memory element 100, depending on the level of a program voltage (V_{PG}) applied through the first and second programming gate electrodes 108, the channel region below the first and second programming gate electrodes may perform any one of the first and second channel operations.

In addition, the triple-gate feedback memory element 100 may be determined to be in any one of an on state and an off state based on the level of a control voltage (V_{CG}) applied through the control gate electrode 107.

Accordingly, the reconfigurable logic-in-memory cell may perform a logical operation function and a memory function based on the level of an output voltage (V_{OUT}) that changes depending on any one state in any one channel operation that has already been performed.

Referring to FIG. 1B, a triple-gate feedback memory element 110 according to one embodiment of the present invention includes a drain region 111, a channel region 112, a source region 113, and a gate region, and the gate region includes first and second programming gate electrodes 118 and a control gate electrode 117, which are formed on a gate insulating film 114.

According to one embodiment of the present invention, the triple-gate feedback memory element 110 includes the drain region 111, the channel region 112, and the source region 113, which are p-i-n nanostructures.

For example, the drain region 111 may be in a p-doped state, the source region 113 may be in an n-doped state, and the channel region 112 may be in an intrinsic state.

In the channel region 112, the channel region below the first and second programming gate electrodes 118 may operate as an n channel corresponding to a first channel operation when the level of a program voltage (V_{PG}) is a high level, and may operate as a p channel corresponding to a second channel operation when the level of the program voltage (V_{PG}) is a low level.

A plurality of triple-gate feedback memory elements 110 may form a reconfigurable logic-in-memory cell.

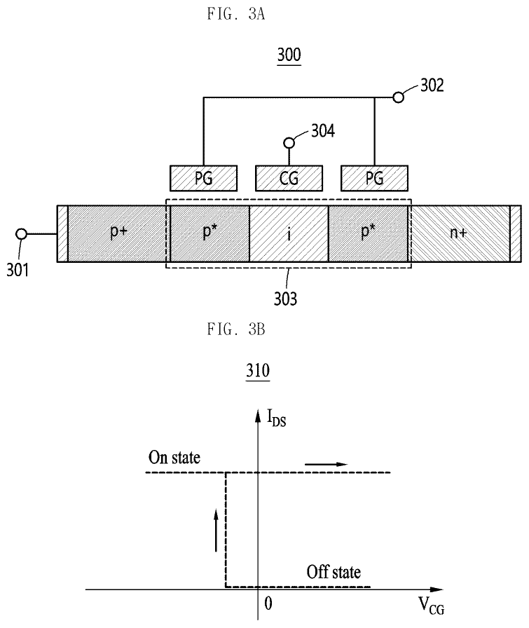

FIGS. 2A and 2B are diagrams explaining the circuitry symbols of a triple-gate feedback memory element according to one embodiment of the present invention.

FIG. 2A shows a circuitry symbol when the channel region of the triple-gate feedback memory element according to one embodiment of the present invention performs a first channel operation and operates as an n channel.

In addition, FIG. 2B shows a circuitry symbol when the channel region of the triple-gate feedback memory element according to one embodiment of the present invention performs a second channel operation and operates as a p channel.

Referring to FIG. 2A, in a triple-gate feedback memory element 200 according to one embodiment of the present invention, in a nanostructure 201 including a drain region, a channel region, a source region, and a gate region, first and second programming gate electrodes and a control gate electrode are formed in a gate region and a programming gate terminal (PG) and a control gate terminal (CG) are connected thereto, a drain electrode is formed in a drain region and a drain terminal (D) is connected thereto, and a source electrode is formed in a source region and a source terminal (S) is connected thereto.

In addition, the symbol of the triple-gate feedback memory element 200 indicates that the triple-gate feedback memory element 200 is in a first channel operation state through a channel operation state region 202.

That is, the symbol of the triple-gate feedback memory element 200 may represent the channel operation state region 202 in a solid form, indicating that the triple-gate feedback memory element 200 is operating as an n channel.

Referring to FIG. 2B, in a triple-gate feedback memory element 210 according to one embodiment of the present invention, a nanostructure 211 including a drain region, a channel region, a source region, and a gate region, first and second programming gate electrodes and a control gate electrode are formed in a gate region and a programming gate terminal (PG) and a control gate terminal (CG) are connected thereto, a drain electrode is formed in a drain region and a drain terminal (D) is connected thereto, and a source electrode is formed in a source region and a source terminal (S) is connected thereto.

In addition, the symbol of the triple-gate feedback memory element 210 indicates that the triple-gate feedback memory element 210 is in a second channel operation state through a channel operation state region 212.

That is, the symbol of the triple-gate feedback memory element 210 may represent the channel operation state region 212 in an empty form, indicating that the triple-gate feedback memory element 210 is operating as a p channel.

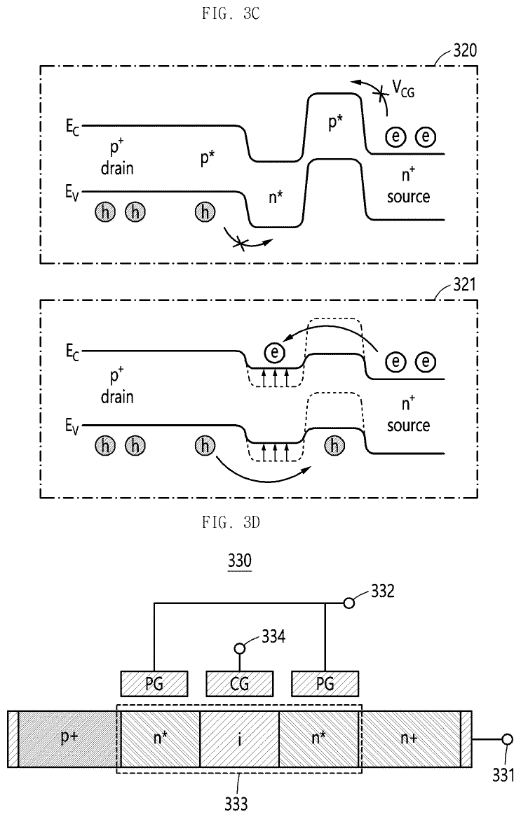

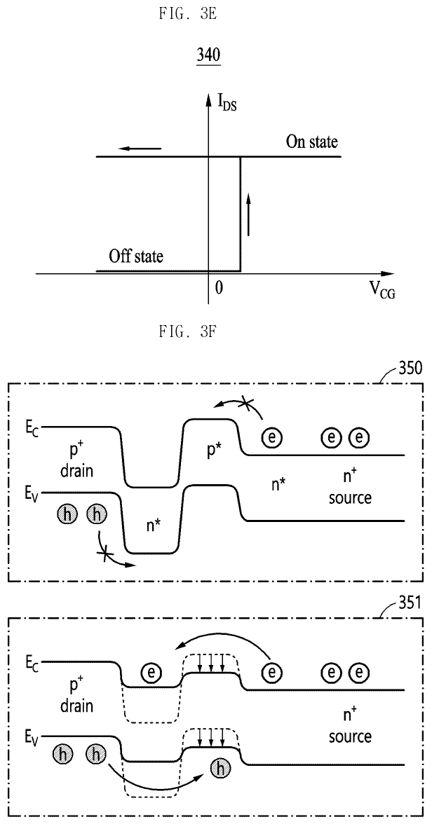

FIGS. 3A to 3F are diagrams explaining the operating principle of a triple-gate feedback memory element according to one embodiment of the present invention.

FIGS. 3A to 3C show an operating principle when the triple-gate feedback memory element according to one embodiment of the present invention operates as a p channel.

Referring to FIG. 3A, in a triple-gate feedback memory element 300 according to one embodiment of the present invention, a positive voltage is applied through a drain terminal 301. When a negative voltage corresponding to the low level of a program voltage is applied to a programming gate terminal 302, in a channel region 303, the channel region below a programming gate electrode (PG) is programmed as a p channel and operates as a p channel.

For example, the triple-gate feedback memory element 300 is determined to be in an on or off state based on the level of a control voltage applied through a control gate terminal 304.

The on and off operating states of the triple-gate feedback memory element 300 are explained with reference to FIGS. 3B and 3C.

Referring to FIG. 3B, when the triple-gate feedback memory element according to one embodiment of the present invention operates as a p channel, an operation state 310 is determined as an on state when the level of a control voltage applied through the control gate terminal is a low level, and is determined as an off state when the level of a control voltage applied through the control gate terminal is a high level.

FIG. 3C illustrates an energy band 320 in an off state and an energy band 321 in an on state based on the level of a control voltage when the triple-gate feedback memory element according to one embodiment of the present invention operates as a p channel.

Referring to the energy band 320 and the energy band 321, when the channel region below the first and second programming gate electrodes performs a second channel operation corresponding to a p channel operation, when the level of a control voltage (V_{CG}) decreases from zero to a low level, the height of the potential barrier between the channel region below the control gate electrode and the channel region below the first programming gate electrode adjacent to the drain region is lowered, and due to the lowered potential barrier, a second positive feedback loop occurs in which holes are injected from the drain region, resulting in an on state in which current flows.

That is, in the triple-gate feedback memory element, a second positive feedback loop occurs, switching from the energy band 320 to the energy band 321.

For example, the second positive feedback loop may be a positive feedback loop in which holes serve as the majority carriers in the channel region.

FIGS. 3D to 3F shows an operating principle when the triple-gate feedback memory element according to one embodiment of the present invention operates as an n channel.

Referring to FIG. 3D, in a triple-gate feedback memory element 330 according to one embodiment of the present invention, a negative voltage is applied through a source terminal 331. When a positive voltage corresponding to the high level of a program voltage is applied to a programming gate terminal 332, in a channel region 333, the channel region below a programming gate electrode (PG) is programmed as an n channel and operates as an n channel.

For example, the triple-gate feedback memory element 330 is determined to be in an on or off state based on the level of a control voltage applied through a control gate terminal 334.

The on and off operating states of the triple-gate feedback memory element 330 are explained with reference to FIGS. 3E and 3F.

Referring to FIG. 3E, when the triple-gate feedback memory element according to one embodiment of the present invention operates as an n channel, an operation state 340 is determined as an on state when the level of a control voltage applied through the control gate terminal is a high level, and is determined as an off state when the level of a control voltage applied through the control gate terminal is a low level.

FIG. 3F illustrates an energy band 350 in an off state and an energy band 351 in an on state based on the level of a control voltage when the triple-gate feedback memory element according to one embodiment of the present invention operates as an n channel.

Referring to the energy band 350 and the energy band 351, when the channel region below the first and second programming gate electrodes performs a first channel operation corresponding to an n channel operation, when the level of a control voltage (V_{CG}) increases from zero to a high level, the height of the potential barrier between the channel region below the control gate electrode and the channel region below the second programming gate electrode adjacent to the source region is lowered, and due to the lowered potential barrier, a first positive feedback loop occurs in which electrons are injected from the source region, resulting in an on state in which current flows.

That is, in the triple-gate feedback memory element, a first positive feedback loop occurs, switching from the energy band 350 to the energy band 351.

For example, the first positive feedback loop may be a positive feedback loop in which electrons serve as the majority carriers in the channel region.

According to one embodiment of the present invention, the triple-gate feedback memory element may be an element in which a first positive feedback loop or a second positive feedback loop is formed depending on the level of a control voltage applied to the gate region, and the on or off state is variably controlled in first and second channel operations.

In addition, in the triple-gate feedback memory element, as charge carriers accumulate in the potential well of the channel region, a positive feedback loop is formed and the triple-gate feedback memory element is turned on, which may be used as a memory function to preserve data in the channel region.

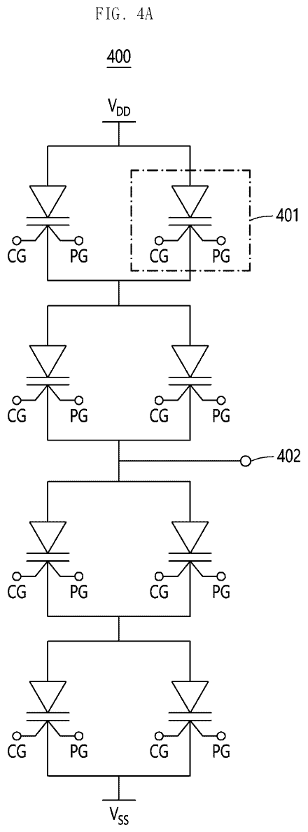

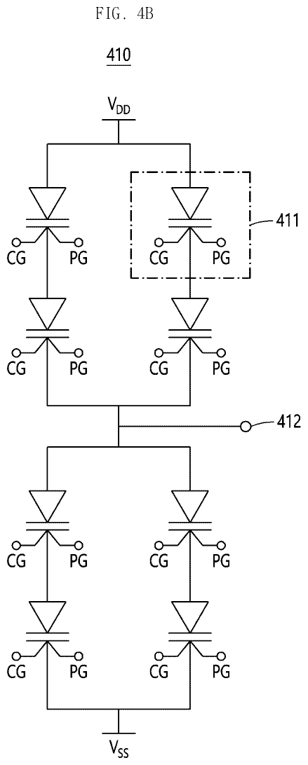

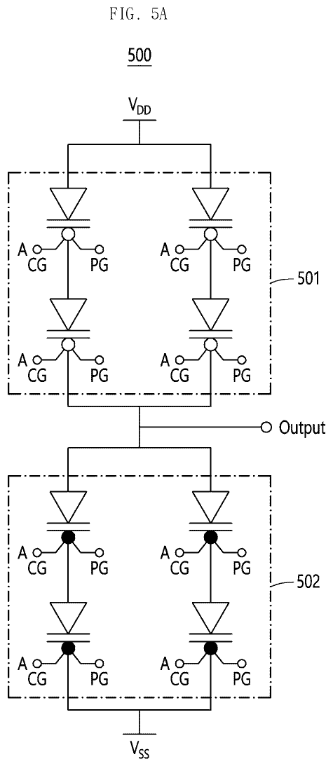

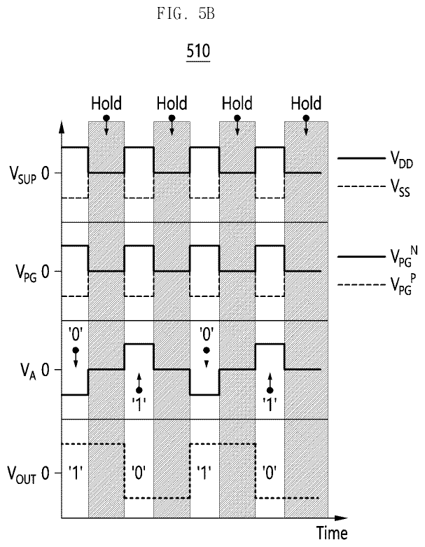

FIGS. 4A and 4B are diagrams explaining the circuitry diagram of a reconfigurable logic-in-memory cell according to one embodiment of the present invention.

FIGS. 4A and 4B show the circuitry diagrams of a reconfigurable logic-in-memory cell consisting of a plurality of triple-gate feedback memory elements according to one embodiment of the present invention.

Referring to FIGS. 4A and 4B, the reconfigurable logic-in-memory cell may be implemented with two types of circuitries.

Referring to FIG. 4A, a reconfigurable logic-in-memory cell 400 according to one embodiment of the present invention is constructed based on a parallel connection where two triple-gate feedback memory elements 401 are connected by connecting a drain region and a source region. Four parallel connections are formed sequentially by connecting the source and the drain.

That is, the reconfigurable logic-in-memory cell 400 according to one embodiment of the present invention exhibits a first circuitry structure consisting of a plurality of first parallel connections where the drain regions of two triple-gate feedback memory elements of a plurality of triple-gate feedback memory elements are connected to each other and the source regions thereof are connected to each other.

For example, when the reconfigurable logic-in-memory cell 400 has the first circuitry structure, a supply voltage is applied by applying a drain voltage (V_{DD}) to the drain terminal of the first of a plurality of first parallel connections and applying a source voltage (V_{SS}) to the source terminal of the last one of the first parallel connections, and logical operations and memory functions may be performed based on the level of an output voltage at an output terminal 402 according to an input voltage applied through the control gate terminal to each of the triple-gate feedback memory elements 401.

Referring to FIG. 4B, a reconfigurable logic-in-memory cell 410 according to one embodiment of the present invention has a second circuitry structure consisting of a plurality of second parallel connections where a common drain region and common source region between a first serial connection where the drain region and source region of two triple-gate feedback memory elements of four triple-gate feedback memory elements 411 are connected in series and a second serial connection wherein the drain region and source region of the remaining two triple-gate feedback memory elements are connected in series are connected.

For example, when the reconfigurable logic-in-memory cell 410 has the second circuitry structure, a supply voltage is applied by applying a drain voltage (V_{DD}) to the drain terminal of the first of a plurality of second parallel connections and applying a source voltage (V_{SS}) to the source terminal of the last one of the second parallel connections, and logical operations and memory functions may be performed based on the level of an output voltage at an output terminal 412 according to an input voltage applied through the control gate terminal to each of the triple-gate feedback memory elements 411.

FIGS. 5A and 5B are diagrams explaining the NOT gate operation of a reconfigurable logic-in-memory cell according to one embodiment of the present invention.

FIG. 5A shows a circuitry diagram in the NOT gate operation of the reconfigurable logic-in-memory cell according to one embodiment of the present invention.

Referring to FIG. 5A, a reconfigurable logic-in-memory cell 500 according to one embodiment of the present invention has the second circuitry structure described in FIG. 4B.

In addition, in the reconfigurable logic-in-memory cell 500, based on a programming voltage applied through a programming gate terminal (PG), triple-gate feedback memory elements constituting a first one 501 of a plurality of second parallel connections perform a second channel operation, and triple-gate feedback memory elements constituting a last one 502 of the second parallel connections perform a first channel operation.

At this time, the reconfigurable logic-in-memory cell 500 may perform a logical operation function corresponding to a NOT gate operation in which the level of an output voltage (V_{OUT}) measured through an output terminal is a high level when the level of a control voltage (V_{CG}), which is an input voltage (V_{A}) applied through a control gate terminal (CG), is a low level, and the level of the output voltage (V_{OUT}) is a low level when the level of the control voltage (V_{CG}) is a high level.

FIG. 5B shows a timing diagram in the NOT gate operation of the reconfigurable logic-in-memory cell according to one embodiment of the present invention.

Referring to FIG. 5B, a timing diagram 510 shows that a high-level output voltage (V_{OUT}) corresponding to ‘1’ is calculated when a low-level input voltage (V_{A}) corresponding to ‘0’ is applied, and a low-level output voltage (V_{OUT}) corresponding to ‘0’ is calculated when a high-level input voltage (V_{A}) corresponding to ‘1’ is applied.

In addition, the timing diagram 510 shows that a memory function that holds a calculated logic value is performed even when a supply voltage (V_{SUP}), a program voltage (V_{PG}), and an input voltage (V_{A}) are removed.

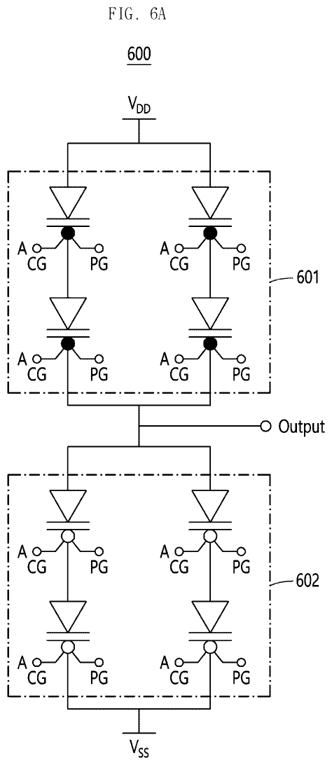

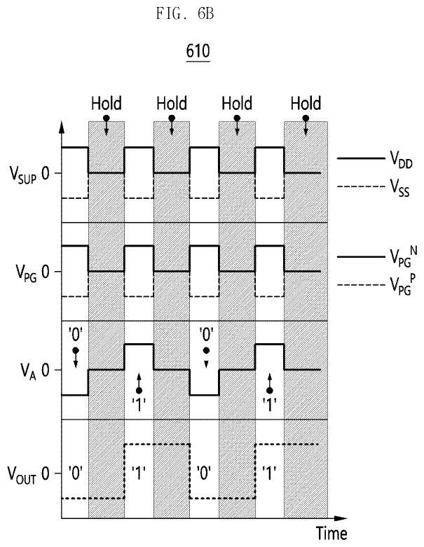

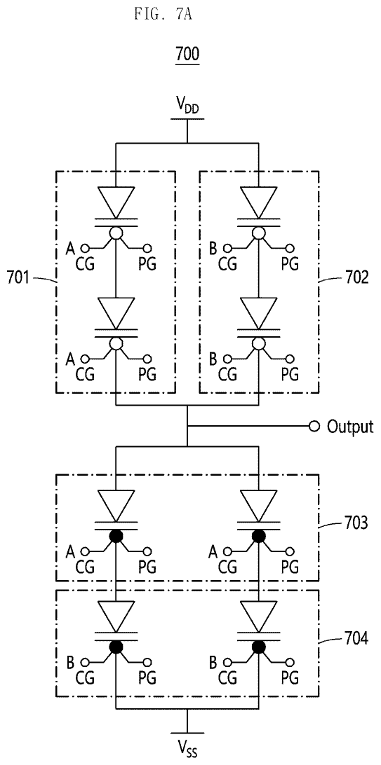

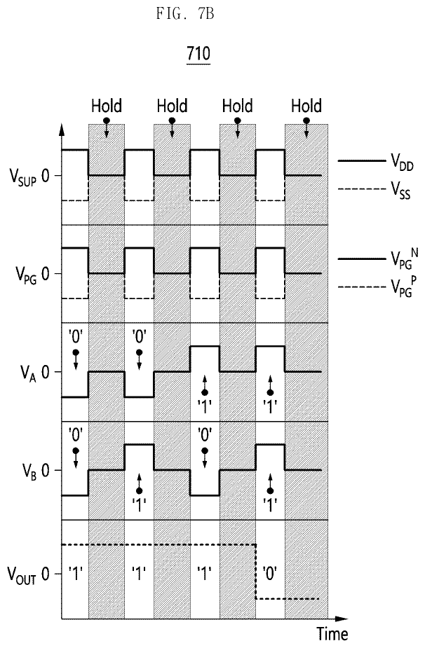

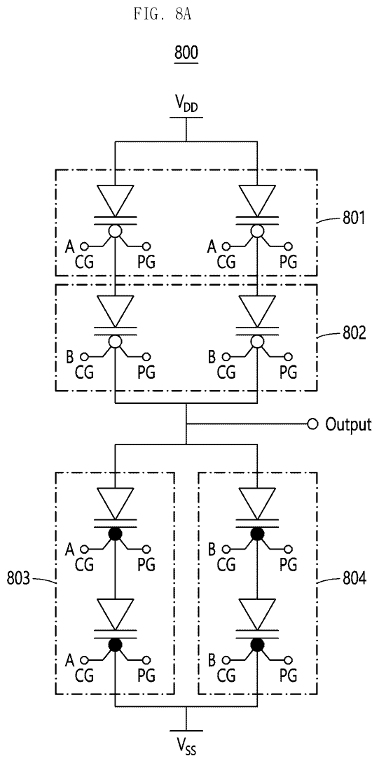

FIGS. 6A and 6B are diagrams explaining the YES gate operation of a reconfigurable logic-in-memory cell according to one embodiment of the present invention.

FIG. 6A shows a circuitry diagram in the YES gate operation of the reconfigurable logic-in-memory cell according to one embodiment of the present invention.

Referring to FIG. 6A, a reconfigurable logic-in-memory cell 600 according to one embodiment of the present invention has the second circuitry structure described in FIG. 4B.

In addition, in the reconfigurable logic-in-memory cell 600, based on a programming voltage applied through a programming gate terminal (PG), triple-gate feedback memory elements constituting a first one 601 of a plurality of second parallel connections perform a first channel operation, and triple-gate feedback memory elements constituting a last one 602 of the second parallel connections perform a second channel operation.

At this time, the reconfigurable logic-in-memory cell 600 may perform a logical operation function corresponding to a YES gate operation in which the level of an output voltage (V_{OUT}) measured through an output terminal is a high level when the level of a control voltage (V_{CG}), which is an input voltage (V_{A}) applied through a control gate terminal (CG), is a high level, and the level of the output voltage (V_{OUT}) is a low level when the level of the control voltage (V_{CG}) is a low level.

FIG. 6B shows a timing diagram in the YES gate operation of the reconfigurable logic-in-memory cell according to one embodiment of the present invention.

Referring to FIG. 6B, a timing diagram 610 shows that a low-level output voltage (V_{OUT}) corresponding to ‘0’ is calculated when a low-level input voltage (V_{A}) corresponding to ‘0’ is applied, and a high-level output voltage (V_{OUT}) corresponding to ‘1’ is calculated when a high-level input voltage (V_{A}) corresponding to ‘1’ is applied.

In addition, the timing diagram 610 shows that a memory function that holds a calculated logic value is performed even when a supply voltage (V_{SUP}), a program voltage (V_{PG}), and an input voltage (V_{A}) are removed.

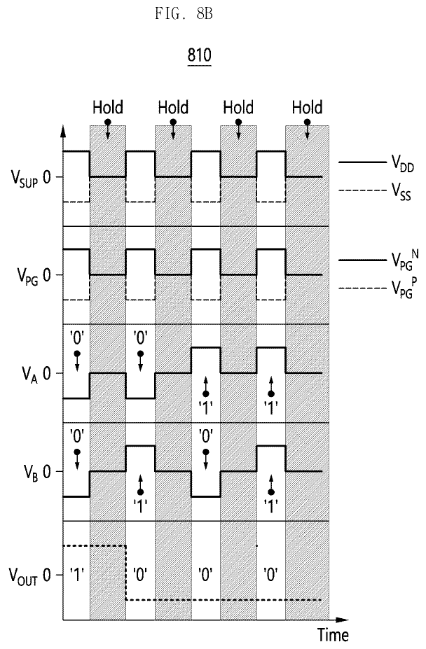

FIGS. 7A and 7B are diagrams explaining the NAND gate operation of a reconfigurable logic-in-memory cell according to one embodiment of the present invention.

FIG. 7A shows a circuitry diagram in the NAND gate operation of the reconfigurable logic-in-memory cell according to one embodiment of the present invention.

Referring to FIG. 7A, a reconfigurable logic-in-memory cell 700 according to one embodiment of the present invention has the second circuitry structure described in FIG. 4B.

For example, in the reconfigurable logic-in-memory cell 700, based on a programming voltage applied through a programming gate terminal (PG), triple-gate feedback memory elements constituting the first one of a plurality of second parallel connections perform a second channel operation, and triple-gate feedback memory elements constituting the last one of the second parallel connections perform a first channel operation.

In addition, in the reconfigurable logic-in-memory cell 700, a first control voltage (V_{A}) of control voltages (V_{CG}) is applied to a left side 701 of the first one of the second parallel connections and an upper side 703 of the last one of the second parallel connections, and a second control voltage (V_{B}) of control voltages (V_{CG}) is applied to a right side 702 of the first one of the second parallel connections and a lower side 704 of the last one of the second parallel connections.

Accordingly, the reconfigurable logic-in-memory cell 700 may perform a logical operation function of an NAND gate in which the level of the output voltage (V_{OUT}) is a high level when only one of the levels of the first control voltage (V_{A}) and the second control voltage (V_{B}) is a high level or both levels are low levels, and the level of the output voltage (V_{OUT}) is a low level when both levels of the first control voltage (V_{A}) and the second control voltage (V_{B}) are high levels.

FIG. 7B shows a timing diagram in the NAND gate operation of the reconfigurable logic-in-memory cell according to one embodiment of the present invention.

Referring to FIG. 7B, a timing diagram 710 shows that when inputs corresponding to ‘00’, ‘01’, ‘10’, and ‘11’ are applied to two input voltages (V_{A}, V_{B}), values corresponding to ‘1’, ‘1’, ‘1’, and ‘0’ at an output voltage (V_{OUT}) are calculated.

In addition, the timing diagram 710 shows that a memory function that holds a calculated logic value is performed even when a supply voltage (V_{SUP}), a program voltage (V_{PG}), and an input voltage (V_{A}) are removed.

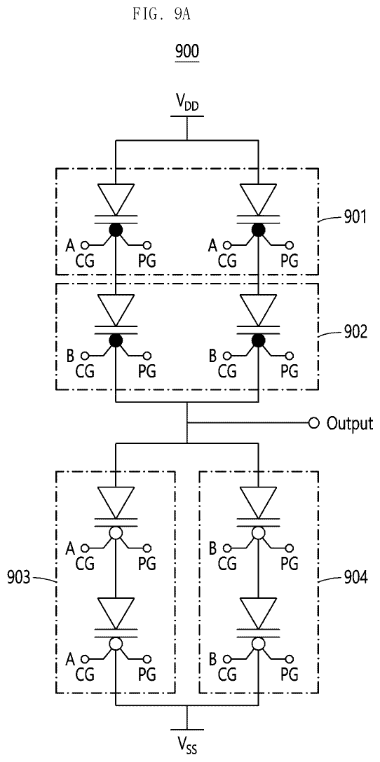

FIGS. 8A and 8B are diagrams explaining the NOR gate operation of a reconfigurable logic-in-memory cell according to one embodiment of the present invention.

FIG. 8A shows a circuitry diagram in the NOR gate operation of the reconfigurable logic-in-memory cell according to one embodiment of the present invention.

Referring to FIG. 8A, a reconfigurable logic-in-memory cell 800 according to one embodiment of the present invention has the second circuitry structure described in FIG. 4B.

For example, in the reconfigurable logic-in-memory cell 800, based on a programming voltage applied through a programming gate terminal (PG), triple-gate feedback memory elements constituting the first one of a plurality of second parallel connections perform a second channel operation, and triple-gate feedback memory elements constituting the last one of the second parallel connections perform a first channel operation.

In addition, in the reconfigurable logic-in-memory cell 800, a first control voltage (V_{A}) of control voltages (V_{CG}) is applied to an upper side 801 of the first one of the second parallel connections and a left side 803 of the last one of the second parallel connections, and a second control voltage (V_{B}) of control voltages (V_{CG}) is applied to a lower side 802 of the first one of the second parallel connections and a right side 804 of the last one of the second parallel connections.

Accordingly, the reconfigurable logic-in-memory cell 800 may perform a logical operation function of an NOR gate in which the level of an output voltage (V_{OUT}) is a low level when only one of the levels of the first control voltage (V_{A}) and the second control voltage (V_{B}) is a low level or both levels are high levels, and the level of the output voltage (V_{OUT}) is a high level when both levels of the first control voltage (V_{A}) and the second control voltage (V_{B}) are low levels.

FIG. 8B shows a timing diagram in the NOR gate operation of the reconfigurable logic-in-memory cell according to one embodiment of the present invention.

Referring to FIG. 8B, a timing diagram 810 shows that when inputs corresponding to ‘00’, ‘01’, ‘10’, and ‘11’ are applied to two input voltages (V_{A}, V_{B}), values corresponding to ‘1’, ‘0’, ‘0’, and ‘0’ at an output voltage (V_{OUT}) are calculated.

In addition, the timing diagram 810 shows that a memory function that holds a calculated logic value is performed even when a supply voltage (V_{SUP}), a program voltage (V_{PG}), and an input voltage (V_{A}) are removed.

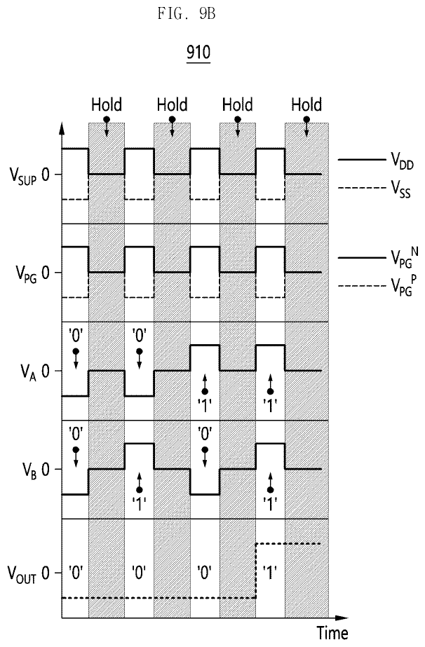

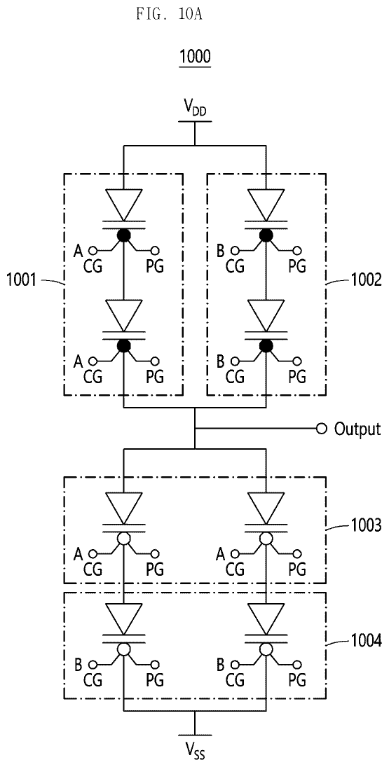

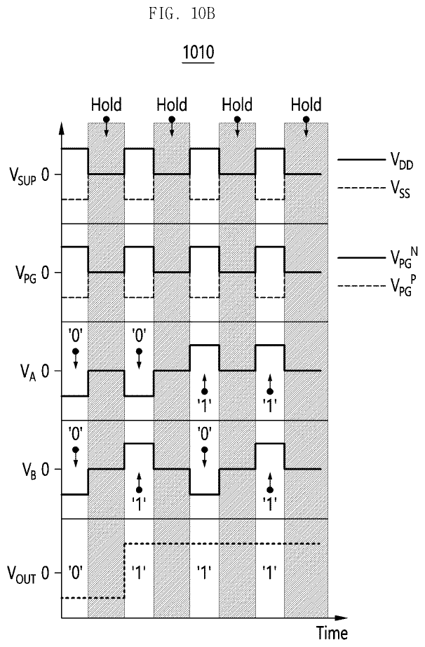

FIGS. 9A and 9B are diagrams explaining the AND gate operation of a reconfigurable logic-in-memory cell according to one embodiment of the present invention.

FIG. 9A shows a circuitry diagram in the AND gate operation of the reconfigurable logic-in-memory cell according to one embodiment of the present invention.

Referring to FIG. 9A, a reconfigurable logic-in-memory cell 900 according to one embodiment of the present invention has the second circuitry structure described in FIG. 4B.

For example, in the reconfigurable logic-in-memory cell 900, based on a programming voltage applied through a programming gate terminal (PG), triple-gate feedback memory elements constituting the first one of a plurality of second parallel connections perform a first channel operation, and triple-gate feedback memory elements constituting the last one of the second parallel connections perform a second channel operation.

In addition, in the reconfigurable logic-in-memory cell 900, a first control voltage (V_{A}) of control voltages (V_{CG}) is applied to an upper side 901 of the first one of the second parallel connections and a left side 903 of the last one of the second parallel connections, and a second control voltage (V_{B}) of control voltages (V_{CG}) is applied to a lower side 902 of the first one of the second parallel connections and a right side 904 of the last one of the second parallel connections.

Accordingly, the reconfigurable logic-in-memory cell 900 may perform a logical operation function of an AND gate in which the level of an output voltage (V_{OUT}) is a low level when any one of the levels of the first control voltage (V_{A}) and the second control voltage (V_{B}) is a low level, and the level of the output voltage (V_{OUT}) is a high level when both levels of the first control voltage (V_{A}) and the second control voltage (V_{B}) are high levels.

FIG. 9B shows a timing diagram in the NAND gate operation of the reconfigurable logic-in-memory cell according to one embodiment of the present invention.

Referring to FIG. 9B, a timing diagram 910 shows that when inputs corresponding to ‘00’, ‘01’, ‘10’, and ‘11’ are applied to two input voltages (V_{A}, V_{B}), values corresponding to ‘0’, ‘0’, ‘0’, and ‘1’ at an output voltage (V_{OUT}) are calculated.

In addition, the timing diagram 910 shows that a memory function that holds a calculated logic value is performed even when a supply voltage (V_{SUP}), a program voltage (V_{PG}), and an input voltage (V_{A}) are removed.

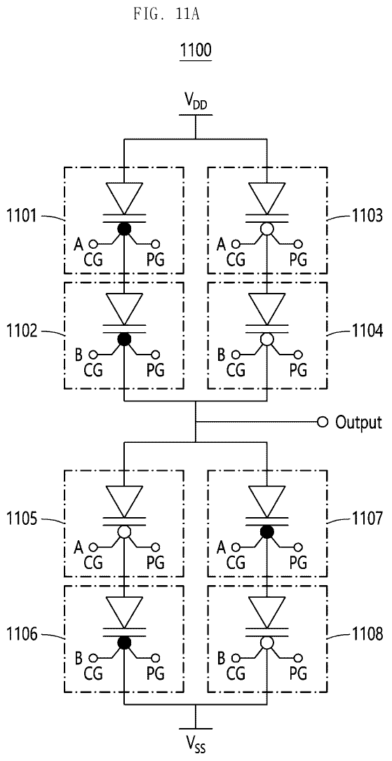

FIGS. 10A and 10B are diagrams explaining the OR gate operation of a reconfigurable logic-in-memory cell according to one embodiment of the present invention.

FIG. 10A shows a circuitry diagram in the OR gate operation of the reconfigurable logic-in-memory cell according to one embodiment of the present invention.

Referring to FIG. 10A, a reconfigurable logic-in-memory cell 1000 according to one embodiment of the present invention has the second circuitry structure described in FIG. 4B.

For example, in the reconfigurable logic-in-memory cell 1000, based on a programming voltage applied through a programming gate terminal (PG), triple-gate feedback memory elements constituting the first one of a plurality of second parallel connections perform a first channel operation, and triple-gate feedback memory elements constituting the last one of the second parallel connections perform a second channel operation.

In addition, in the reconfigurable logic-in-memory cell 1000, a first control voltage (V_{A}) of control voltages (V_{CG}) is applied to a left side 1001 of the first one of the second parallel connections and an upper side 1003 of the last one of the second parallel connections, and a second control voltage (V_{B}) of control voltages (V_{CG}) is applied to a right side 1002 of the first one of the second parallel connections and a lower side 1004 of the last one of the second parallel connections.

Accordingly, the reconfigurable logic-in-memory cell 1000 may perform a logical operation function of an OR gate in which the level of an output voltage (V_{OUT}) is a high level when any one of the levels of the first control voltage (V_{A}) and the second control voltage (V_{B}) is a high level, and the level of the output voltage (V_{OUT}) is a low level when both levels of the first control voltage (V_{A}) and the second control voltage (V_{B}) are low levels.

FIG. 10B shows a timing diagram in the OR gate operation of the reconfigurable logic-in-memory cell according to one embodiment of the present invention.

Referring to FIG. 10B, a timing diagram 1010 shows that when inputs corresponding to ‘00’, ‘01’, ‘10’, and ‘11’ are applied to two input voltages (V_{A}, V_{B}), values corresponding to ‘0’, ‘1’, ‘1’, and ‘1’ at an output voltage (V_{OUT}) are calculated.

In addition, the timing diagram 1010 shows that a memory function that holds a calculated logic value is performed even when a supply voltage (V_{SUP}), a program voltage (V_{PG}), and an input voltage (V_{A}) are removed.

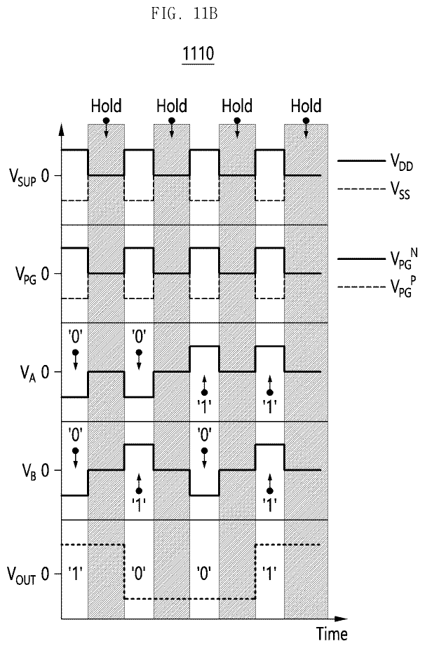

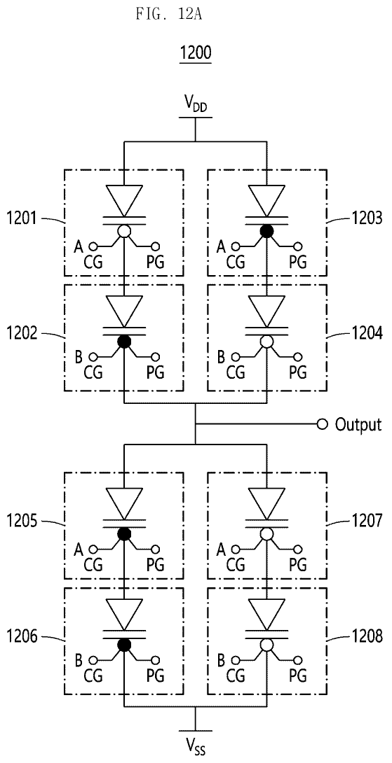

FIGS. 11A and 11B are diagrams explaining the XNOR gate operation of a reconfigurable logic-in-memory cell according to one embodiment of the present invention.

FIG. 11A shows a circuitry diagram in the XNOR gate operation of the reconfigurable logic-in-memory cell according to one embodiment of the present invention.

Referring to FIG. 11A, a reconfigurable logic-in-memory cell 1100 according to one embodiment of the present invention has the second circuitry structure described in FIG. 4B.

In the reconfigurable logic-in-memory cell 1100, the left side of triple-gate feedback memory elements constituting the first one of a plurality of second parallel connections performs a first channel operation, and the right side thereof performs a second channel operation. The upper left side of triple-gate feedback memory elements constituting the last one of the second parallel connections performs a second channel operation, the upper right side thereof performs a first channel operation, the lower left side thereof performs a first channel operation, and the lower right side thereof performs a second channel operation.

The first one of the second parallel connections may include a first triple-gate feedback memory element 1101 and a second triple-gate feedback memory element 1102. The first triple-gate feedback memory element 1101 and the second triple-gate feedback memory element 1102 may be included in the left side of triple-gate feedback memory elements constituting the first one of the second parallel connections.

In addition, the first one of the second parallel connections include a third triple-gate feedback memory element 1103 and a fourth triple-gate feedback memory element 1104. The third triple-gate feedback memory element 1103 and the fourth triple-gate feedback memory element 1104 may be included in the right side of triple-gate feedback memory elements constituting the first one of the second parallel connections.

In addition, in the reconfigurable logic-in-memory cell 1100, a first control voltage (V_{A}) of control voltages (V_{CG}) is applied to the upper side of the first one of the second parallel connections and the upper side of the last one of the second parallel connections, and a second control voltage (V_{B}) of control voltages (V_{CG}) is applied to the lower side of the first one of the second parallel connections and the lower side of the last one of the second parallel connections.

The last one of the second parallel connections may include a fifth triple-gate feedback memory element 1105 and a sixth triple-gate feedback memory element 1106. The fifth triple-gate feedback memory element 1105 and the sixth triple-gate feedback memory element 1106 may be included in the left side of triple-gate feedback memory elements constituting the last one of the second parallel connections.

In addition, the last one of the second parallel connections may include a seventh triple-gate feedback memory element 1107 and an eighth triple-gate feedback memory element 1108. The seventh triple-gate feedback memory element 1107 and the eighth triple-gate feedback memory element 1108 may be included in the right side of triple-gate feedback memory elements constituting the last one of the second parallel connections.

The reconfigurable logic-in-memory cell 1100 according to one embodiment of the present invention may perform a logical operation function of an XNOR gate in which the level of an output voltage (V_{OUT}) is a high level when the levels of the first control voltage (V_{A}) and the second control voltage (V_{B}) are the same, and the level of the output voltage (V_{OUT}) is a low level when the levels of the first control voltage (V_{A}) and the second control voltage (V_{B}) are different.

FIG. 11B shows a timing diagram in the XNOR gate operation of the reconfigurable logic-in-memory cell according to one embodiment of the present invention.

Referring to FIG. 11B, a timing diagram 1110 shows that when inputs corresponding to ‘00’, ‘01’, ‘10’, and ‘11’ are applied to two input voltages (V_{A}, V_{B}), values corresponding to ‘1’, ‘0’, ‘0’, and ‘1’ at an output voltage (V_{OUT}) are calculated.

In addition, the timing diagram 1110 shows that a memory function that holds a calculated logic value is performed even when a supply voltage (V_{SUP}), a program voltage (V_{PG}), and an input voltage (V_{A}) are removed.

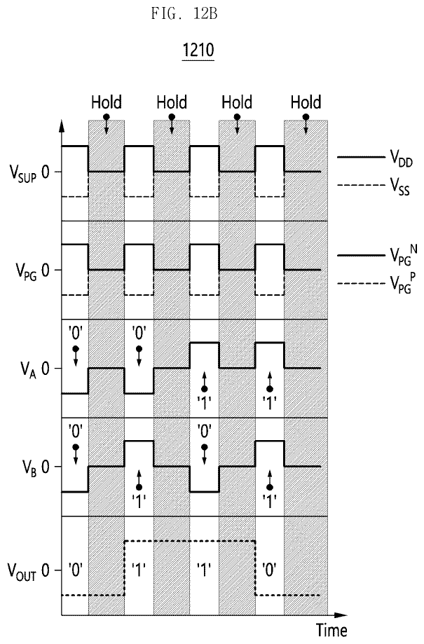

FIGS. 12A and 12B are diagrams explaining the XOR gate operation of a reconfigurable logic-in-memory cell according to one embodiment of the present invention.

FIG. 12A shows a circuitry diagram in the XOR gate operation of the reconfigurable logic-in-memory cell according to one embodiment of the present invention.

Referring to FIG. 12A, a reconfigurable logic-in-memory cell 1200 according to one embodiment of the present invention has the second circuitry structure described in FIG. 4B.

In the reconfigurable logic-in-memory cell 1200, the upper left side of triple-gate feedback memory elements constituting the first one of a plurality of second parallel connections performs a second channel operation, the upper right side thereof performs a first channel operation, the lower left side thereof performs a first channel operation, and the lower right side thereof performs a second channel operation. The left side of triple-gate feedback memory elements constituting the last one of the second parallel connections performs a first channel operation and the right side thereof performs a second channel operation.

The first one of the second parallel connections may include a first triple-gate feedback memory element 1201 and a second triple-gate feedback memory element 1202. The first triple-gate feedback memory element 1201 and the second triple-gate feedback memory element 1202 may be included in the left side of triple-gate feedback memory elements constituting the first one of the second parallel connections.

In addition, the first one of the second parallel connections may include a third triple-gate feedback memory element 1203 and a fourth triple-gate feedback memory element 1204. The third triple-gate feedback memory element 1203 and the fourth triple-gate feedback memory element 1204 may be included in the right side of triple-gate feedback memory elements constituting the first one of the second parallel connections.

In addition, in the reconfigurable logic-in-memory cell 1200, a first control voltage (V_{A}) of control voltages (V_{CG}) may be applied to the upper side of the first one of the second parallel connections and the upper side of the last one of the second parallel connections.

In addition, in the reconfigurable logic-in-memory cell 1200, a second control voltage (V_{B}) of control voltages (V_{CG}) may be applied to the lower side of the first one of the second parallel connections and the lower side of the last one of the second parallel connections.

The last one of the second parallel connections may include a fifth triple-gate feedback memory element 1205 and a sixth triple-gate feedback memory element 1206. The fifth triple-gate feedback memory element 1205 and the sixth triple-gate feedback memory element 1206 may be included in the left side of triple-gate feedback memory elements constituting the last one of the second parallel connections.

In addition, the last one of the second parallel connections may include a seventh triple-gate feedback memory element 1207 and an eighth triple-gate feedback memory element 1208. The seventh triple-gate feedback memory element 1207 and the eighth triple-gate feedback memory element 1208 may be included in the right side of triple-gate feedback memory elements constituting the last one of the second parallel connections.

The reconfigurable logic-in-memory cell 1200 according to one embodiment of the present invention may perform a logical operation function of an XOR gate in which the level of an output voltage (V_{OUT}) is a low level when the levels of the first control voltage (V_{A}) and the second control voltage (V_{B}) are the same, and the level of the output voltage (V_{OUT}) is a high level when the levels of the first control voltage (V_{A}) and the second control voltage (V_{B}) are different.

FIG. 12B shows a timing diagram in the XOR gate operation of the reconfigurable logic-in-memory cell according to one embodiment of the present invention.

Referring to FIG. 12B, a timing diagram 1210 shows that when inputs corresponding to ‘00’, ‘01’, ‘10’, and ‘11’ are applied to two input voltages (V_{A}, V_{B}), values corresponding to ‘0’, ‘1’, ‘1’, and ‘0’ at an output voltage (V_{OUT}) are calculated.

In addition, the timing diagram 1210 shows that a memory function that holds a calculated logic value is performed even when a supply voltage (V_{SUP}), a program voltage (V_{PG}), and an input voltage (V_{A}) are removed.

In the above-described specific embodiments, elements included in the disclosure are expressed in singular or plural in accordance with the specific embodiments shown.

It should be understood, however, that the singular or plural representations are to be chosen as appropriate to the situation presented for the purpose of description and that the above-described embodiments are not limited to the singular or plural constituent elements. The constituent elements expressed in plural may be composed of a single number, and constituent elements expressed in singular form may be composed of a plurality of elements.

In addition, the present invention has been described with reference to exemplary embodiments, but it should be understood that various modifications may be made without departing from the scope of the present invention.

Therefore, the scope of the present invention should not be limited by the embodiments, but should be determined by the following claims and equivalents to the following claims.

1. A reconfigurable logic-in-memory cell, comprising a plurality of triple-gate feedback memory elements comprising a drain region, a channel region, a source region, and a gate region where first and second programming gate electrodes and a control gate electrode are formed on the channel region,
wherein, in each of the triple-gate feedback memory elements, the channel region below the first and second programming gate electrodes performs any one channel operation of first and second channel operations depending on a level of a program voltage (V_{PG}) applied through the first and second programming gate electrodes, any one of an on state and an off state is determined based on a level of a control voltage (V_{CG}) applied through the control gate electrode, and a logical operation function and a memory function are performed based on a level of an output voltage (V_{OUT}) that changes depending on the any one state in the any one channel operation performed.

2. The reconfigurable logic-in-memory cell according to claim 1, wherein the drain region is in a p-doped state, the source region is in an n-doped state, and the channel region is in an intrinsic state,
wherein the channel region below the first and second programming gate electrodes operates as an n channel corresponding to the first channel operation when a level of the program voltage (V_{PG}) is a high level, and operates as a p channel corresponding to the second channel operation when a level of the program voltage (V_{PG}) is a low level.

3. The reconfigurable logic-in-memory cell according to claim 1, wherein, when the channel region below the first and second programming gate electrodes performs the first channel operation, each of the triple-gate feedback memory elements is determined to be in an on state when a level of the applied control voltage (V_{CG}) is a high level, and is determined to be in an off state when a level of the applied control voltage (V_{CG}) is a low level.

4. The reconfigurable logic-in-memory cell according to claim 3, wherein, in each of the triple-gate feedback memory elements, when the channel region below the first and second programming gate electrodes performs the first channel operation, when a level of the applied control voltage (V_{CG}) increases from zero to a high level, a height of a potential barrier between the channel region below the control gate electrode and the channel region below the second programming gate electrode adjacent to the source region is lowered, and due to the lowered potential barrier, a first positive feedback loop in which electrons are injected from the source region occurs, resulting in the on state in which current flows.

5. The reconfigurable logic-in-memory cell according to claim 1, wherein, when the channel region below the first and second programming gate electrodes performs the second channel operation, each of the triple-gate feedback memory elements is determined to be in an off state when a level of the applied control voltage (V_{CG}) is a high level, and is determined to be in an on state when a level of the applied control voltage (V_{CG}) is a low level.

6. The reconfigurable logic-in-memory cell according to claim 5, wherein, in each of the triple-gate feedback memory elements, when the channel region below the first and second programming gate electrodes performs the second channel operation, when a level of the applied control voltage (V_{CG}) decreases from zero to a low level, a height of a potential barrier between the channel region below the control gate electrode and the channel region below the first programming gate electrode adjacent to the drain region is lowered, and due to the lowered potential barrier, a second positive feedback loop in which holes are injected from the drain region occurs, resulting in the on state in which current flows.

7. The reconfigurable logic-in-memory cell according to claim 1, wherein the reconfigurable logic-in-memory cell consists of any one circuitry structure of a first circuitry structure consisting of a plurality of first parallel connections where drain regions of two triple-gate feedback memory elements of the triple-gate feedback memory elements are connected to each other and source regions thereof are connected to each other; and a second circuitry structure consisting of a plurality of second parallel connections where a common drain region and a common source region between a first serial connection where a drain region and source region of two triple-gate feedback memory elements of four triple-gate feedback memory elements of the triple-gate feedback memory elements are connected in series and a second serial connection where a drain region and source region of the remaining two triple-gate feedback memory elements are connected in series are connected.

8. The reconfigurable logic-in-memory cell according to claim 7, wherein, when the reconfigurable logic-in-memory cell has the first circuitry structure, a drain voltage (V_{DD}) is applied to a drain terminal of a first one of the first parallel connections, and a source voltage (V_{SS}) is applied to a source terminal of a last one of the first parallel connections; and
when the reconfigurable logic-in-memory cell has the second circuitry structure, a drain voltage (V_{DD}) is applied to a drain terminal of a first one of the second parallel connections, and a source voltage (V_{SS}) is applied to a source terminal of a last one of the second parallel connections.

9. The reconfigurable logic-in-memory cell according to claim 8, wherein the reconfigurable logic-in-memory cell has the second circuitry structure; triple-gate feedback memory elements constituting a first one of the second parallel connections perform the second channel operation, and triple-gate feedback memory elements constituting a last one of the second parallel connections perform the first channel operation; and the reconfigurable logic-in-memory cell performs the logical operation function in which a level of the output voltage (V_{OUT}) is a high level when a level of the control voltage (V_{CG}) is a low level, and a level of the output voltage (V_{OUT}) is a low level when a level of the control voltage (V_{CG}) is a high level.

10. The reconfigurable logic-in-memory cell according to claim 8, wherein the reconfigurable logic-in-memory cell has the second circuitry structure; triple-gate feedback memory elements constituting a first one of the second parallel connections perform the first channel operation, and triple-gate feedback memory elements constituting a last one of the second parallel connections perform the second channel operation; and the reconfigurable logic-in-memory cell performs the logical operation function in which a level of the output voltage (V_{OUT}) is a low level when a level of the control voltage (V_{CG}) is a low level, and a level of the output voltage (V_{OUT}) is a high level when a level of the control voltage (V_{CG}) is a high level.

11. The reconfigurable logic-in-memory cell according to claim 8, wherein the reconfigurable logic-in-memory cell has the second circuitry structure; triple-gate feedback memory elements constituting a first one of the second parallel connections perform the second channel operation, and triple-gate feedback memory elements constituting a last one of the second parallel connections perform the first channel operation; a first control voltage (V_{A}) of the control voltages (V_{CG}) is applied to a left side of the first one of the second parallel connections and an upper side of the last one of the second parallel connections, and a second control voltage (V_{B}) of the control voltages (V_{CG}) is applied to a right side of the first one of the second parallel connections and a lower side of the lase one of the second parallel connections; and the reconfigurable logic-in-memory cell performs the logical operation function in which a level of the output voltage (V_{OUT}) is a high level when only one of levels of the first control voltage (V_{A}) and the second control voltage (V_{B}) is a high level or both levels are low levels, and a level of the output voltage (V_{OUT}) is a low level when both levels of the first control voltage (V_{A}) and the second control voltage (V_{B}) are high levels.

12. The reconfigurable logic-in-memory cell according to claim 8, wherein the reconfigurable logic-in-memory cell has the second circuitry structure; triple-gate feedback memory elements constituting a first one of the second parallel connections perform the second channel operation, and triple-gate feedback memory elements constituting a last one of the second parallel connections perform the first channel operation; a first control voltage (V_{A}) of the control voltages (V_{CG}) is applied to an upper side of the first one of the second parallel connections and a left side of the last one of the second parallel connections, and a second control voltage (V_{B}) of the control voltages (V_{CG}) is applied to a lower side of the first one of the second parallel connections and a right side of the last one of the second parallel connections; and the reconfigurable logic-in-memory cell performs the logical operation function in which a level of the output voltage (V_{OUT}) is a low level when only one of levels of the first control voltage (V_{A}) and the second control voltage (V_{B}) is a low level or both levels are high levels, and a level of the output voltage (V_{OUT}) is a high level when both levels of the first control voltage (V_{A}) and the second control voltage (V_{B}) are low levels.

13. The reconfigurable logic-in-memory cell according to claim 8, wherein the reconfigurable logic-in-memory cell has the second circuitry structure; triple-gate feedback memory elements constituting a first one of the second parallel connections perform the first channel operation, and triple-gate feedback memory elements constituting a last one of the second parallel connections perform the second channel operation; a first control voltage (V_{A}) of the control voltages (V_{CG}) is applied to an upper side of the first one of the second parallel connections and a left side of the last one of the second parallel connections, and a second control voltage (V_{B}) of the control voltages (V_{CG}) is applied to a lower side of the first one of the second parallel connections and a right side of the last one of the second parallel connections; and the reconfigurable logic-in-memory cell performs the logical operation function in which a level of the output voltage (V_{OUT}) is a low level when any one of levels of the first control voltage (V_{A}) and the second control voltage (V_{B}) is a low level, and a level of the output voltage (V_{OUT}) is a high level when both levels of the first control voltage (V_{A}) and the second control voltage (V_{B}) are high levels.

14. The reconfigurable logic-in-memory cell according to claim 8, wherein the reconfigurable logic-in-memory cell has the second circuitry structure; triple-gate feedback memory elements constituting a first one of the second parallel connections perform the first channel operation, and triple-gate feedback memory elements constituting a last one of the second parallel connections perform the second channel operation; a first control voltage (V_{A}) of the control voltages (V_{CG}) is applied to a left side of the first one of the second parallel connections and an upper side of the last one of the second parallel connections, and a second control voltage (V_{B}) of the control voltages (V_{CG}) is applied to a right side of the first one of the second parallel connections and a lower side of the last one of the second parallel connections; and the reconfigurable logic-in-memory cell performs the logical operation function in which a level of the output voltage (V_{OUT}) is a high level when any one of levels of the first control voltage (V_{A}) and the second control voltage (V_{B}) is a high level, and a level of the output voltage (V_{OUT}) is a low level when both levels of the first control voltage (V_{A}) and the second control voltage (V_{B}) are low levels.

15. The reconfigurable logic-in-memory cell according to claim 8, wherein the reconfigurable logic-in-memory cell has the second circuitry structure; a left side of triple-gate feedback memory elements constituting a first one of the second parallel connections performs the first channel operation, a right side of the triple-gate feedback memory elements constituting the first one of the second parallel connections performs the second channel operation, an upper left side of triple-gate feedback memory elements constituting a last one of the second parallel connections performs the second channel operation, an upper right side of the triple-gate feedback memory elements constituting the last one of the second parallel connections performs the first channel operation, a lower left side of the triple-gate feedback memory elements constituting the last one of the second parallel connections performs the first channel operation, and a lower right side of the triple-gate feedback memory elements constituting the last one of the second parallel connections performs the second channel operation; a first control voltage (V_{A}) of the control voltages (V_{CG}) is applied to an upper side of the first one of the second parallel connections and an upper side of the last one of the second parallel connections, and a second control voltage (V_{B}) of the control voltages (V_{CG}) is applied to a lower side of the first one of the second parallel connections and a lower side of the last one of the second parallel connections; and the reconfigurable logic-in-memory cell performs the logical operation function in which a level of the output voltage (V_{OUT}) is a high level when levels of the first control voltage (V_{A}) and the second control voltage (V_{B}) are the same, and a level of the output voltage (V_{OUT}) is a low level when levels of the first control voltage (V_{A}) and the second control voltage (V_{B}) are different.

16. The reconfigurable logic-in-memory cell according to claim 8, wherein the reconfigurable logic-in-memory cell has the second circuitry structure; an upper left side of triple-gate feedback memory elements constituting a first one of the second parallel connections performs the second channel operation, an upper right side of the triple-gate feedback memory elements constituting the first one of the second parallel connections performs the first channel operation, a lower left side of the triple-gate feedback memory elements constituting the first one of the second parallel connections performs the first channel operation, a lower right side of the triple-gate feedback memory elements constituting the first one of the second parallel connections performs the second channel operation, a left side of triple-gate feedback memory elements constituting a last one of the second parallel connections performs the first channel operation, and a right side of the triple-gate feedback memory elements constituting the last one of the second parallel connections performs the second channel operation; a first control voltage (V_{A}) of the control voltages (V_{CG}) is applied to an upper side of the first one of the second parallel connections and an upper side of the last one of the second parallel connections, and a second control voltage (V_{B}) of the control voltages (V_{CG}) is applied to a lower side of the first one of the second parallel connections and a lower side of the last one of the second parallel connections; and the reconfigurable logic-in-memory cell performs the logical operation function in which a level of the output voltage (V_{OUT}) is a low level when levels of the first control voltage (V_{A}) and the second control voltage (V_{B}) are the same, and a level of the output voltage (V_{OUT}) is a high level when levels of the first control voltage (V_{A}) and the second control voltage (V_{B}) are different.

17. The reconfigurable logic-in-memory cell according to claim 8, wherein the reconfigurable logic-in-memory cell performs the memory function by maintaining a level of the output voltage (V_{OUT}) when the drain voltage (V_{DD}), the source voltage (V_{SS}), the program voltage (V_{PG}), and the control voltage (V_{CG}) are applied at a zero level.
